(19) United States
(12) Patent Application Publication
(10) Pub. No.: US 2006/0071298 A1
(43) Pub. Date: Apr. 6, 2006

(54) Polysilicon memory element

(76) Inventors: Kelvin Yupak Hui, Fremont, CA (US); Man Sun Chan, Hong Kong (HK)

Correspondence Address: TROP PRUNER & HU, PC, 8554 KATY FREEWAY, SUITE 100, HOUSTON, TX, 77024, US

(21) Appl. No.: 10/958,440

(22) Filed: Oct. 5, 2004

(51) Int. Cl. H01L 29/00

(52) U.S. Cl. 257/544

(57) ABSTRACT

A memory element may be formed from a polysilicon PN junction. In one state, the junction exhibits the characteristics of a diode. After exposure to a reverse bias breakdown voltage, the junction may exhibit the characteristics of a resistor. Thus, two different states may be detected by determining the characteristics of the diode. In addition, the diode may be erased by exposing the device with the resistor characteristics to still higher reverse bias conditions creating an open circuit. Because of the grain boundary conditions in the polysilicon PN junction, the breakdown of the junction is permanent.

### BACKGROUND

This invention relates generally to memory elements including fuses, antifuses, and memory arrays using semiconductor memory.

The demand for high density and low cost semiconductor memory has increased dramatically in recent years. In particular, non-volatile memory embedded with common circuits is particularly important for permanent information storage for that information pertaining to a particular chip. Non-volatile memories do not lose data even without power supply. A non-volatile memory may be a one time programmable (OTP) or a reprogrammable memory. A one time programmable memory can be programmed once and the data stored becomes permanent.

Most existing one time programmable memory technologies are based on antifuse technology involving breaking down an insulating dielectric and forming a conduction path. This approach becomes more difficult to apply to deep submicron complementary metal oxide semiconductor processes below certain sizes due to the leakage that occurs, making it difficult to breakdown thin dielectrics. In addition, technologies proposed for one time programmable memory may require extra masks in addition to standard processing techniques.

Thus, there is a need for better ways to make new semiconductor memory elements.

### BRIEF DESCRIPTION OF THE DRAWINGS

FIG. 1 is a schematic depiction of one embodiment of the present invention;

FIG. 2 is an enlarged, cross-section of a device in accordance with one embodiment of the present invention at an early stage of manufacture;

FIG. 3 is an enlarged, cross-section of the device shown in FIG. 2 at a subsequent stage of manufacture in accordance with one embodiment of the present invention;

FIG. 4 is an enlarged, cross-sectional view of the embodiment shown in FIG. 3 at a subsequent stage of manufacture in accordance with one embodiment of the present invention;

FIG. 5 is an enlarged, cross-sectional view of the embodiment shown in FIG. 4 at a subsequent stage of manufacture in accordance with one embodiment of the present invention;

FIG. 6 is an enlarged, cross-sectional view at a subsequent stage of manufacture in accordance with one embodiment of the present invention;

FIG. 7 is an enlarged, top plan view of the embodiment shown in FIGS. 2-6 in accordance with one embodiment of the present invention;

FIG. 8 is an enlarged, top plan view of another embodiment of the present invention;

FIG. 9 is an enlarged, top plan view of still another embodiment of the present invention;

FIG. 10 is an enlarged, top plan view of still another embodiment of the present invention;

FIG. 11 is an enlarged, top plan view of still another embodiment of the present invention;

FIG. 12 is an enlarged, top plan view of yet another embodiment of the present invention;

FIG. 13 is an enlarged, top plan view of another embodiment of the present invention;

FIG. 14 is an enlarged, top plan view of still another embodiment of the present invention;

FIG. 15 is an enlarged, top plan view of still another embodiment of the present invention;

FIG. 16 is an enlarged, top plan view of still another embodiment of the present invention;

FIG. 17 is an enlarged, top plan view of another embodiment of the present invention;

FIG. 18 is an enlarged, top plan view of another embodiment of the present invention; and

FIG. 19 is a plot of current versus voltage for one embodiment of the present invention.

### DETAILED DESCRIPTION

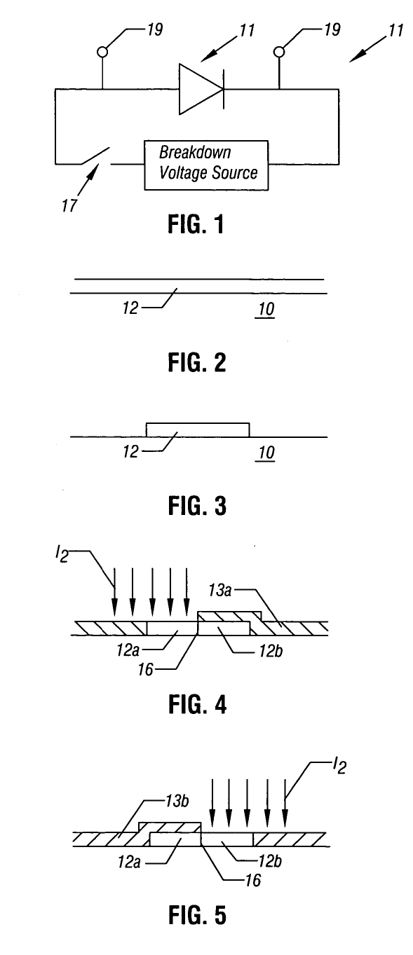

Referring to FIG. 1, a polysilicon PN junction memory element 13 may be connected in a circuit including a pair of spaced ports 19 to enable the state of the element 13 to be monitored. The element 13 is connected via a switch 17 to a breakdown voltage source 15. The voltage source 15 may provide a reverse bias at two levels. At a first level, the reverse bias may be sufficient to cause permanent breakdown of the polysilicon PN junction that forms the element 13. At a second voltage, in some cases, the voltage may be sufficient to form an open circuit. Thus, the memory element 13 may be programmably broken down. It transitions from a normal, unbrokendown state, where it acts as a diode and exhibits diode characteristics. After breakdown, due to exposure to a substantial negative breakdown voltage provided by the source 15, the memory element 13 acts as a resistor.

Thus, in some embodiments of the present invention, by probing the ports 19 one may determine the current voltage characteristics of the memory element 13. Then, one can determine whether the memory element 13 is in one state or the other based on whether or not it exhibits the characteristics of a diode or a resistor.

One method for manufacturing the element 13 is shown in FIGS. 2-6. Initially, a layer of polysilicon 12 may be deposited on the semiconductor substrate 10 as shown in FIG. 2. The layer of polysilicon 12 may be patterned as shown in FIG. 3.

Then, in FIG. 4, one half of the polysilicon 12 may be covered by a mask 13a while the other half is exposed to an impurity. Thus, in FIG. 4, only the portion 12a is exposed to the implantation I₁. The surrounding substrate 10 and the portion 12b of the polysilicon 12 is protected by the mask 13a. The implant I₁ may be of a first conductivity type, either n-type or p-type, to dope the polysilicon portion 12a accordingly.

Then, the mask 13a is removed and replaced with a mask 13b which exposes the polysilicon portion 12b as shown in FIG. 5. The portion 12b is then subjected to an implant I₂ which is of the opposite conductivity type as the implant I₁. As a result, the portions 12a and 12b of opposite conductivity type are formed, having an intervening junction 16.

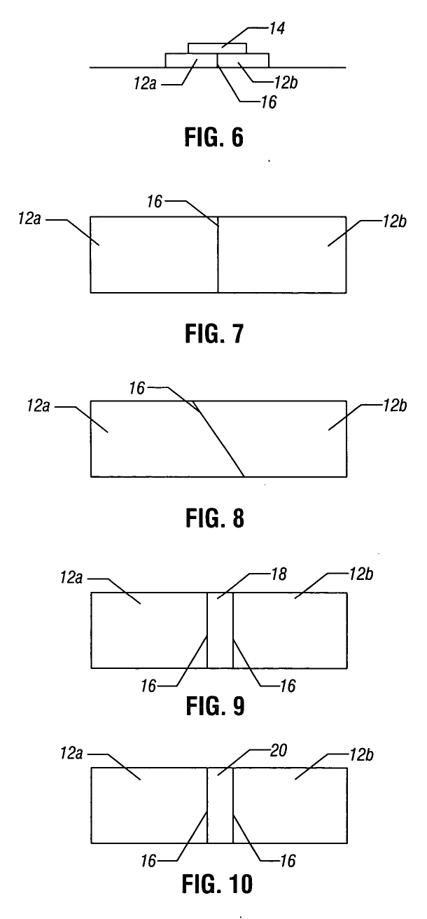

Finally, referring to FIG. 6, in some embodiments, the junction 16 may be protected by a suitable silicide block 14 to prevent silicide formation during subsequent high temperature steps, if any. Thereafter, appropriate contacts can be formed to each of the portions 12a and 12b to form the element 13 shown in FIG. 1.

Then, the element 13, acting as a diode, may be programmed. The element may be broken down by exposure to a sufficiently high voltage from the source 15.

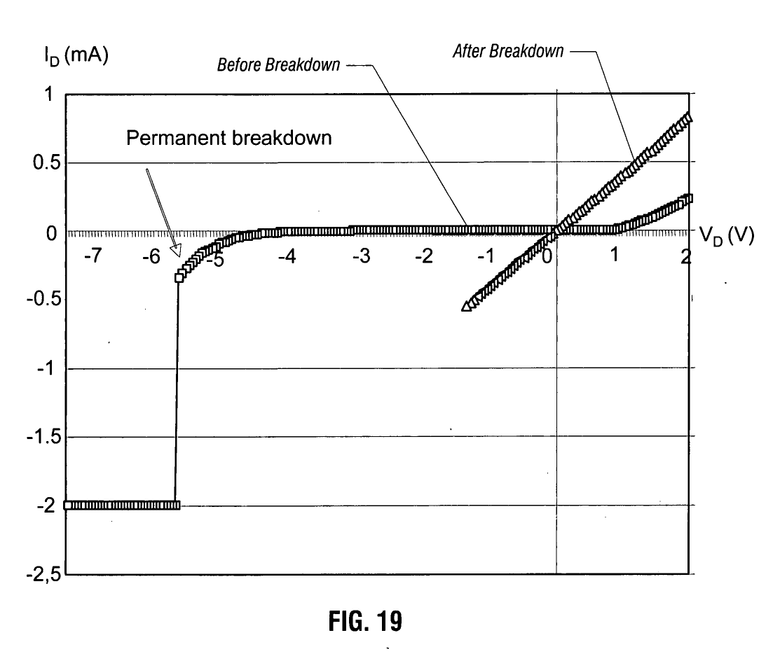

Referring to FIG. 19, a typical iv curve is shown wherein after about −5.5 volts, a permanent breakdown occurs in the diode characteristics of the element 13. Thus, in this illustrative example only, the breakdown voltage source 15 applies a negative voltage of about 5.5 volts to permanently breakdown the element 13. After breakdown, it exhibits linear characteristics indicative of a resistor. As a result, by monitoring the ports 19, it is possible to determine which of the two states the element 13 is in, enabling the element 13 to store data.

Referring to FIG. 7, in one embodiment of the present invention, the element 13 may be formed of two rectangular portions 12a and 12b of polysilicon doped oppositely to form a junction 16. Other non-rectangular shapes are also possible.

FIG. 8 shows a variation in which the junction 16 is formed at an angle. This may be done, as one example, using appropriately shaped masks 13. The angle of the junction 16, shown in FIG. 8, provides a sharp point which may enhance the local electric field and create a weak spot to aid in junction breakdown in some embodiments.

As still another example, shown in FIG. 9, an isolation region 18 may be provided which is substantially undoped. In this case, junctions 16 are formed on either side of the region 18, each junction 16 bordering one of the regions 12a or 12b. The separation 18, shown in FIG. 9, may result in lower leakage current in some embodiments.

Referring to FIG. 10, in this case, a doubly doped region 20 may be formed which is exposed to both conductivity types. The region 20, again, has two junctions 16 as indicated. The region 20 of overlap may cause local enhancement of the electric field at the junctions 16 in some cases.

It is very important to reduce the reverse junction leakage current, to ensure a large differential current between a programmed and virgin cell, and more important, to make it easier to breakdown the polysilicon diode and reduce the current loading by the unprogrammed cells.

In some embodiments, in the brokendown state, the resistance of the element 13 may be relatively low. For example, a resistance on the order of 2500 Ohms may be achieved. However, other resistance values may also be used in other embodiments.

In the embodiments described above, a one time programmable device is implemented. The element 13 initially exhibits diode characteristics and after exposure to a substantial reverse bias, it permanently exhibits the characteristics of a resister. By “permanently” it is intended to refer to the fact that once the diode is broken down, it cannot be reestablished. The breakdown is due to the fact that polysilicon has a grain boundary that enhances the breakdown at the junction, causing permanent damage to the junction and transforming it to become a resistor. The existence of the grain boundary enhances the electric field across the grain boundary, so that a lower reverse voltage may be used to breakdown the junction.

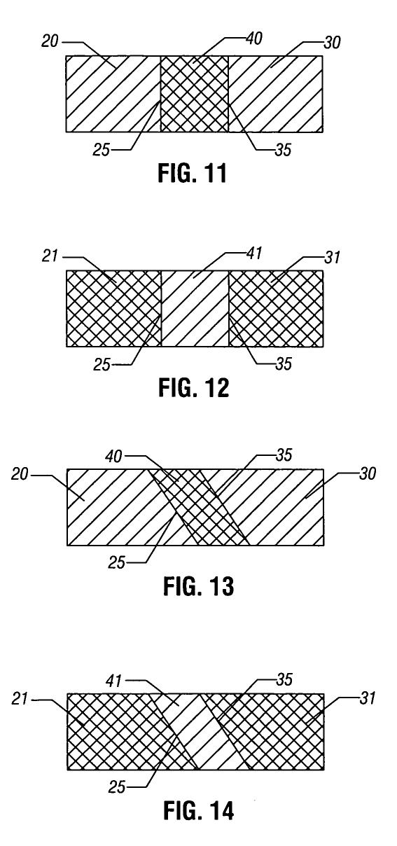

Multiple junctions or double junctions may be provided as shown in FIGS. 11-18. A double junction may be used to store two bits per unit cell. The extra bit of storage can be used to increase memory density or as redundancy in case the programming of one bit is not distinct enough for identification.

Before any junction breakdown occurs, a two junction structure of the format n+/p+/n+ or p+/n+/p+ behaves as an open circuit because one of the junctions will always be reverse biased. Referring to FIG. 11, a structure with a p+ polysilicon region 20, an n+ polysilicon region 40, and a p+ polysilicon region 30 is illustrated. When a positive voltage is applied to the region 20, the junction 25 between the region 20 and the region 30 is forward biased, but the junction 35 between the region 40 and the region 30 is reverse biased. Thus, the structure appears as an open in this circumstance.

A major part of the applied voltage is dropped at the junction 35 between the region 40 and the region 30. When a sufficiently high voltage is applied, the junction 35 between the region 40 and the region 30 can be permanently broken down to form a resistor between the region 40 and the region 30. The device between the region 20 and the region 30, acts as a rectifying diode.

When a positive voltage is applied to region 20 relative to region 30, current flows through the forward biased junction 25 between the regions 20 and 40 and through the resistor to the region 30. When a negative voltage is applied to the region 20 relative to the voltage on the region 30, the junction 25 between region 20 and region 40 is reverse biased and does not allow any current to pass.

Further programming of the structure is possible, however. After the junction 35 between the region 40 and the region 30 is broken down, a high positive voltage can be applied to the region 30 relative to the region 20 so that the junction 25 between the region 20 and the region 40 is reverse biased. When the voltage across the junction 25 is sufficiently high, this junction 25 can be broken down and the behavior of the device from region 20 to region 30 becomes that of a resistor rather than a diode. The combination of open, rectifying diode and pure resistor characteristics allow distinction among different states in the memory device.

FIG. 12 shows a similar structure with opposite conductivity types for the regions 21, 41 and 31. FIG. 13 is a similar structure except that the intermediate region 40, which may be n+ polysilicon, is formed as an angled band so that the junctions 25 and 35 are angular and have sharp points which may encourage breakdown. The structure shown in FIG. 14 is the same as FIG. 13 except the conductivity types of the regions 21, 41, and 31 are reversed.

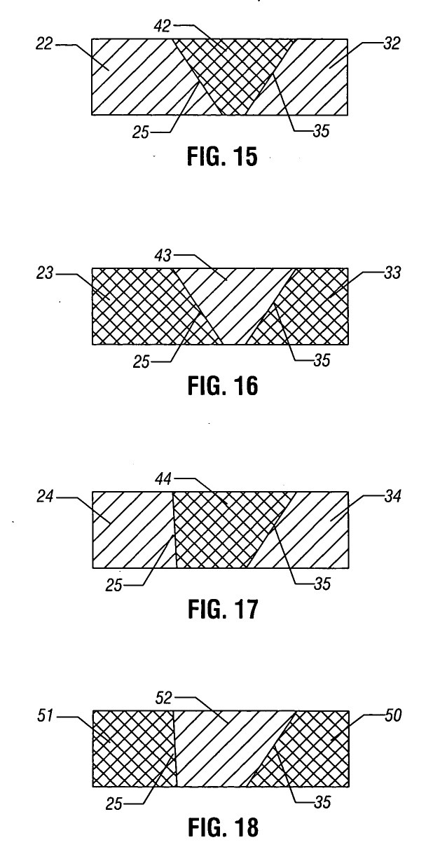

Another structure is shown in FIG. 15 in which the intermediate portion 42 is V-shaped, having junctions 25 and 35. FIG. 16 corresponds to FIG. 15, but is of the opposite conductivity types.

FIG. 17 shows still another arrangement in which the junction 25 is more or less vertical and the junction 35 is angled. FIG. 18 shows the same structure with opposite conductivity types.

In addition to the function as an antifuse forming a resistor, the p+/n+ junctions can be further programmed to become an open or to behave like a fuse. This can be done by continuously applying the reverse bias to the programmed junction under conditions that generate high power or longer programming duration to convert the resistor behavior to an open circuit. Applying reverse bias after the p+/n+ junction is programmed to become a resistor still allows the energy dissipation to be concentrated at the junction. This is more efficient than using a forward bias programming. Similar fuse characteristics can also be achieved by applying high powered forward bias to flow through the junction, breaking it down.

With a double junction structure, after both junctions are broken down, the structure can be converted back to an open circuit similar to the initial state before programming. This reversion may be achieved by applying the poly-fuse programming with high power biasing. In such case, the memory element 13 may be considered a one time programmable, one time erasable memory.

The efficiency of making the p+/n+ junction as a fuse can be enhanced by introducing a lightly doped or undoped region so that more energy is dissipated at the junction for the same current. It can be achieved by using the non-overlap p+/n+ doping method shown in FIG. 9 with the isolation rejoin 18. Silicide blocking can also be used to prevent the formation of silicide at the junction when the technology includes silicide.

In some embodiments a high on state/off state current ratio is established by modifying the p-n junction sharpness. In other words the amount of p+ and n+ overlap may be controlled. Also the polysilicon width may be adjusted or edge tapered to increase on state/off state current ratio.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
exposing a polysilicon PN junction to a reverse bias to program it to have resistor-like characteristics.

2. The method of claim 1 including exposing said PN junction having resistor like characteristics to additional reverse bias to create an open circuit characteristic.

3. The method of claim 1 including forming patterned polysilicon, and doping a first portion of said polysilicon with one conductivity type and a second portion with an opposite conductivity type to form a PN junction.

4. The method of claim 3 including forming said PN junction with said portions in abutment.

5. The method of claim 3 including forming said portions spaced from one another.

6. The method of claim 3 including forming an overlapping junction made up of overlapping P and N type impurities.

7. The method of claim 3 including blocking the formation of a silicide at said junction.

8. The method of claim 1 including forming a first region having a first conductivity type and second and third regions having an opposite conductivity type such that a PN junction is formed on opposite sides of said first region.

9. The method of claim 3 including forming the junction in a transverse arrangement to the length of the patterned polysilicon.

10. The method of claim 3 including forming said junction in an acute angle to the length of said patterned polysilicon.

11. A memory element comprising:
a permanently broken down, polysilicon PN junction.

12. The element of claim 11 including a p+ and an n+ polysilicon region.

13. The element of claim 12 wherein said regions are abutting.

14. The element of claim 12 wherein said regions are spaced apart.

15. The element of claim 12 wherein said regions are overlapping.

16. The element of claim 11, including a strip of polysilicon and said junction is formed in said strip transverse to the length of said strip.

17. The element of claim 11 including a strip of polysilicon and said junction is formed at an angle to the length of said strip.

18. The element of claim 11 including a silicide block over said junction.

19. The element of claim 11 including a region of a first conductivity type between a pair of regions of an opposite conductivity type.

20. The element of claim 11 having the i-v characteristics of a resistor.

21. The element of claim 11 including a polysilicon strip having a feature size of 0.25 microns or less.
